(19) United States
(12) Patent Application Publication
(10) Pub. No.: US 2019/0093218 A1
(43) Pub. Date: Mar. 28, 2019

(54) IN-SITU DRY CLEAN OF TUBE FURNACE

(71) Applicant: Taiwan Semiconductor Manufacturing Co., Ltd., Hsin-Chu (TW)

(72) Inventors: Eddy Lay, Hsinchu City (TW); Shih-Fang Chen, Zhubei City (TW); Shun-Chin Chen, Zhubei City (TW)

(21) Appl. No.: 16/115,139

(22) Filed: Aug. 28, 2018

Related U.S. Application Data
(60) Provisional application No. 62/564,899, filed on Sep. 28, 2017.

(51) Int. Cl. C23C 16/44; H01J 37/32

(52) U.S. Cl. CPC C23C 16/4405; H01J 37/32357; H01J 37/32449; H01J 2237/334; H01J 37/32981; H01J 2237/335; C23C 16/4412

(57) ABSTRACT

Methods and systems for dry cleaning a semiconductor processing reaction chamber are disclosed herein. In some embodiments, a method for cleaning a semiconductor processing reaction chamber includes: performing a plasma-assisted cleaning process to clean tube deposits formed on an inner surface of the deposition reaction chamber, the plasma-assisted cleaning process comprises: providing a first reactant gas to a remote plasma source chamber to generate a plasma, wherein the plasma comprising a fluorine-containing radical; and providing the plasma from the remote plasma source chamber to the deposition reaction chamber to clean the tube deposits, and performing a chemical cleaning process by providing a second reactant gas to the deposition reaction chamber after performing the plasma dry cleaning process.

### RELATED APPLICATION

This application claims the benefit of and priority to U.S. Patent Provisional Application No. 62/564,899, filed on Sep. 28, 2017, the content of which is incorporated herein.

### BACKGROUND

Semiconductor processing involves a number of different chemical and physical processes to construct multilayered films of interrelated patterns. Many of these films are deposited in a tube furnace type of system, which is very cost-effective. Such “hotwall” furnace systems, however, suffer from a film buildup on the reaction chamber inner surfaces, causing unacceptably high levels of particulate contamination on the wafer surface and affecting the deposition conditions. To overcome these problems, frequent cleaning of furnace reaction chambers (e.g., furnace tubes) is necessary to achieve and maintain high production yields. Undesired tube deposits can be removed from the inner surfaces of the reaction chamber by a wet cleaning process known as an ex-situ cleaning process. The process can be time-consuming and can also increase the risk of cross-contamination.

On the other hand, tube deposits can also be removed from the reaction chamber inner surfaces by a dry cleaning process based on in-situ plasma-assisted etching, which can remove tube deposits quickly and can minimize the tool downtime. However, the same reactant gas for etching the tube deposits can also attack the reaction chamber causing unwanted over etching to the tube surface, especially when the tube deposits comprise same elements as those in the tube. Consequently, there exists a need for a method of cleaning Si-based reaction chambers with Si-based tube deposits. For at least the foregoing reasons, conventional techniques for cleaning reaction chambers are not entirely satisfactory.

### BRIEF DESCRIPTION OF THE DRAWINGS

Aspects of the present disclosure are best understood from the following detailed description when read with the accompanying figures. It is noted that various features are not necessarily drawn to scale. In fact, the dimensions and geometries of the various features may be arbitrarily increased or reduced for clarity of illustration.

FIG. 1 illustrates a flow chart of a dry-cleaning method to clean a reaction chamber, in accordance with some embodiments.

FIG. 2 illustrates a schematic of a plasma-assisted dry-cleaning system integrated to a reaction chamber furnace, in accordance with some embodiments.

### DETAILED DESCRIPTION OF EMBODIMENTS

The following disclosure describes various exemplary embodiments for implementing different features of the subject matter. Specific examples of components and arrangements are described below to simplify the present disclosure. These are, of course, merely examples and are not intended to be limiting. For example, it will be understood that when an element is referred to as being “connected to” or “coupled to” another element, it may be directly connected to or coupled to the other element, or one or more intervening elements may be present.

The presented disclosure provides various embodiments of a method and a system for plasma-assisted cleaning of reaction chambers. Such system can be integrated to a semiconductor processing tube reactor for in-situ dry cleaning purposes. This method allows an effective cleaning of the semiconductor processing reaction chamber without causing unwanted over-etching to the tube, or introducing a significant downtime to the tool. Accordingly, the above-mentioned issues maybe advantageously avoided.

This description of the exemplary embodiments is set to be understood in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

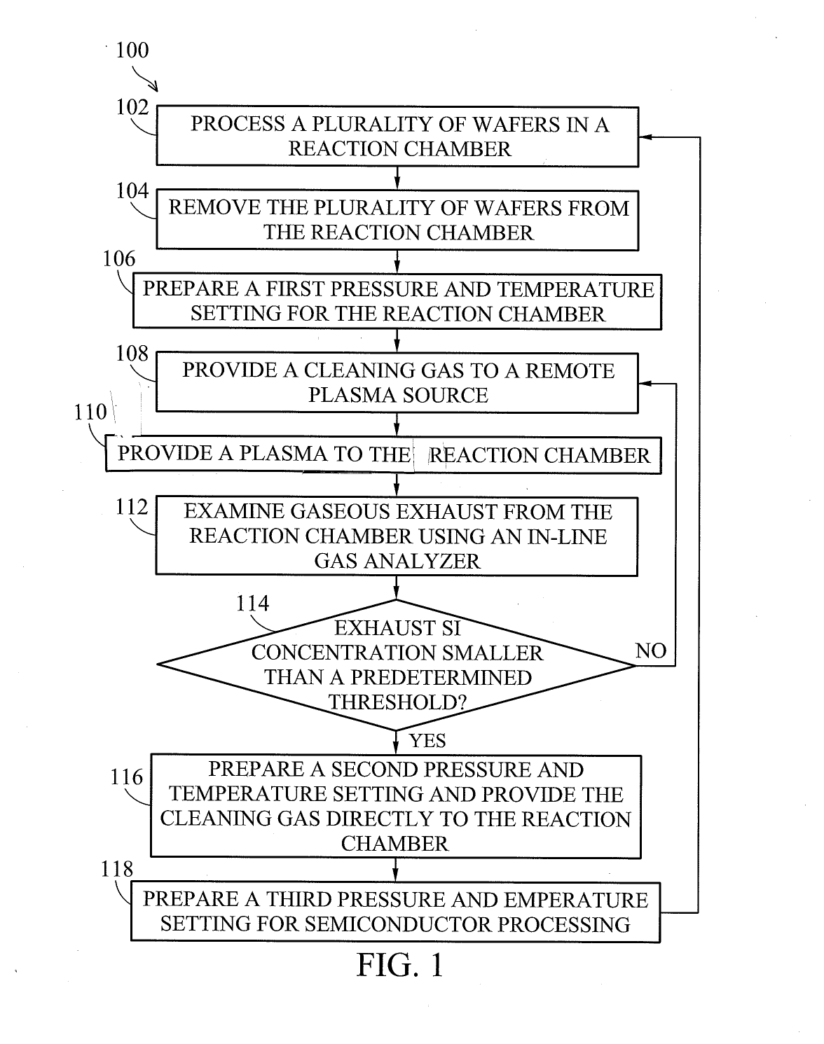

FIG. 1 illustrates a flow chart of a dry-cleaning method 100 to clean a reaction chamber, in accordance with some embodiments. In some embodiments, the reaction chamber is used for deposition of semiconductor materials. The semiconductor materials may be Si or Si containing materials, e.g., poly-Si, Si oxide, Si nitride, or other suitable materials. The method 100 starts with operation 102, wherein one or more wafers can be provided into a reaction chamber for semiconductor processing. In order to improve manufacturing efficiencies and reduce production costs, the size of wafers steadily increased over the years. Standard silicon wafer sizes have steadily grown from about 200 mm (about 8 inches in diameter) to 300 mm (about 12 inches in diameter). The next generation wafer standard has been set for 450 mm (about 18 inches in diameter). The next generation wafer size of 450 mm has created a challenge in maintaining a uniform environment (e.g., temperature and reactant distribution) in the wafer stacks throughout the wafer boat during a CVD process that is desired to promote uniform material film deposition on a surface of each wafer. In some embodiments, the reaction chamber can be used for processing of large wafers (e.g. 12-18 inches in diameter). In some embodiments, the reaction chamber can be integrated with automated control systems and transfer mechanisms for loading and unloading wafers. The plurality of wafers can be processed together as a stack on a carrier (e.g., wafer boat) or processed individually, in accordance with some embodiments. The tube furnace can be a horizontal tube furnace, vertical tube furnace, a rotary tube furnace, a vacuum tube furnace, and can also be a reactor type of furnace with a larger reaction chamber.

The method 100 continues with operation 104, where the film deposition process on the plurality of wafers is completed. The plurality of wafers can be unloaded from the reaction chamber after the temperature changes (e.g., drops) from a deposition temperature to a threshold temperature in order to safely open the reaction chamber to transfer the plurality of wafers to a next processing station or to a storage station. Temperatures of CVD processes may vary from a hundred to a thousand degrees Celsius depending on the type of materials to be deposited and reactant to be used for depositing such materials.

The method 100 continues with operation 106, where a first temperature and pressure setting of the reaction chamber is prepared. In operations 106-114, a plasma-assisted cleaning process is performed in the reaction chamber under the first temperature and pressure condition. The plasma-assist cleaning process is configured to remove (or etch) materials formed on the inner surface of the reaction chamber, which is referred to as “tube deposits” hereinafter. In some embodiments, the first pressure setting in the plasma-assisted cleaning process is maintained at a value on the order of a few torr so as to minimize the loss of atomic reactants due to recombination at a higher pressure and to sustain the plasma. In some embodiments, the first temperature setting can be in a range of 200-500 degrees Celsius, depending on the type of tube deposits to be cleaned. Particularly, the temperature can be adjusted based on the desired etching rate and the thickness of the tube deposits. In some embodiments, the reaction chamber can be purged with inert gas to terminate the CVD deposition reaction for precise thickness control.

The method 100 continues with operation 108, in which at least one reactant gas is provided to a remote plasma source according to some embodiment. In some embodiments, the reactant gases may be fluorine-containing reactant gases or other suitable gases. Remote plasma cleaning was designed to remedy the disadvantages of other radio frequency (RF) plasma cleaning, which suffered from a number of deficiencies such as, for example, a slow etch rate, an inability to clean parts that are not in direct exposure to the plasma, sputter erosion from ion bombardment, and incomplete dissociation of reactant gas. In contrast to RF cleaning, remote plasma cleaning involves a purely chemical reaction rather than a combination of ion bombardment and chemically induced reactions. Therefore, some characteristic features of a remote plasma dry clean process include the production, transport and reaction rate of the active species.

In some embodiments, the at least one reactant gas is supplied to the remote plasma source, which is then dissociated into its constituent atoms. In some embodiments, the at least one reactant gas after the remote plasma is dissociated into a plasma comprising charged atoms or ionic species. In some embodiments, a discharge unit in the remote plasma source can be based on technologies such as, for example microwave, radio frequency (RF), etc. In some embodiments, the dissociation fraction of the at least one reactant gas in the remote plasma source can exceed 95%. It should be noted that the dissociation fraction is affected by the range of operation (e.g., flow rate and/or pressure), dissociation efficiency, and resistance to erosion from chemical attachment and ion bombardment. In some embodiments, NF₃, F₂, or a mixture of the two can be also used as fluorine sources. In some embodiments, since the etch rate is directly proportional to the local concentration of fluorine atoms in etching of the tube deposits with Si-containing compounds, inert carrier gas (e.g., Ar or N₂) can be used and controlled by adjusting the flow rate relative to that of the at least one reactant gas. In addition, an inert gas may be used to ignite and sustain the operation of the plasma in the remote plasma source. In some embodiments, a remote plasma source that can handle a large flow rate of the at least one reactant gas can be used in order to achieve acceptable cleaning rates, for example, in large reaction chambers for the processing of large wafers.

The method 100 continues with operation 110, in which the plasma generated from the at least one reactant gas in the remote plasma source is then provided to the reaction chamber according to some embodiments. In some embodiments, the plasma is used in the reaction chamber to perform the plasma-assisted etching process to the tube deposits. The ionic species in the plasma may pass from the remote plasma source to the interior of the reaction chamber through a short transport region made of inert materials to minimize loss of active ionic species through back reactions, reactions at surfaces and/or minimize cooling at the transport region, in accordance with some embodiments. In the reaction chamber, the dissociated active species can react with the tube deposits, converting them to volatile compounds which can be removed as a gas exhaust from the reaction chamber. In some embodiments, temperature of the tube surface can be controlled by a sidewall heater so as to control the etching rate and volatilization which are thermally activated.

The method continues with operation 112, in which the gas exhaust containing volatile compounds from the plasma-assisted cleaning process in the reaction chamber is examined using an in-line gas analyzer according to some embodiments. In some embodiments, the in-line gas analyzer is coupled directly to the exhaust gas line from the reaction chamber. The in-line gas analyzer provides a fast and accurate non-contact measurement technique for evaluating the composition of the exhaust gas, e.g., the Si concentration or the change of Si concentration. In some embodiments, the in-line gas analyzer can be a Fourier Transform Infrared (FTIR) spectrometer, a gas chronometry mass spectrometer (GCMS), etc. In some embodiments, when the Si concentration in the gas exhaust is greater than a predefined threshold value, it means that the tube deposits in the reaction chamber is still in a large amount, and the method returns to operation 108 where the plasma-assisted cleaning process continues. In some embodiments, a predetermined threshold is determined as a function of flow rate and history of the reaction chamber, such as, for example number of processing cycles, temperature, type of tube deposits, cleaning conditions, etc.

In some embodiments, when the Si concentration in the gas exhaust is equal to or smaller than the predefined threshold value, it means that there is almost no tube deposit in the reaction chamber, and the method 100 continues with operation 116, in which the plasma-assisted cleaning process is terminated, a second pressure and temperature setting of the reaction chamber is prepared, and the reactant gas is provided directly to the reaction chamber according to some embodiments. In some embodiments, the remote plasma source can be either switched off or bypassed to provide the at least one reactant gas directly to the reaction chamber, in accordance with some embodiments. Since a chemical reaction using a fluorine-containing reactant gas is much slower due to a higher activation energy compared to the chemical reaction using a plasma, the second temperature setting in operation 116 can be higher than the first temperature setting used in operation 110. In some embodiments, the second pressure setting can be also greater than the first pressure setting in order to provide the reactant gas with a higher concentration. In some embodiments, the second pressure setting is in a range of a few hundred torr. Operation 116 can ensure a precise control of the cleaning of the tube deposits and minimizing the chance of over-etching to the reaction chamber. In some embodiments, in operation 116, the at least one reactant gas in the chemical cleaning process comprises a Hydrogen-containing gas, including HF, H₂, etc, in order to tune the etching rate.

The method 100 further continues with operation 118, in which a third pressure and temperature setting to the reaction chamber is prepared for semiconductor processing according to some embodiments. In some embodiments, the third pressure and temperature setting is determined according to materials and deposition conditions of the corresponding semiconductor processing. In some embodiments, an additional step to condition the inner tube surface is conducted before the loading of a next batch of wafers for the semiconductor processing. It should be noted that various set-up and purge steps may also be included before or after any steps in the method 100.

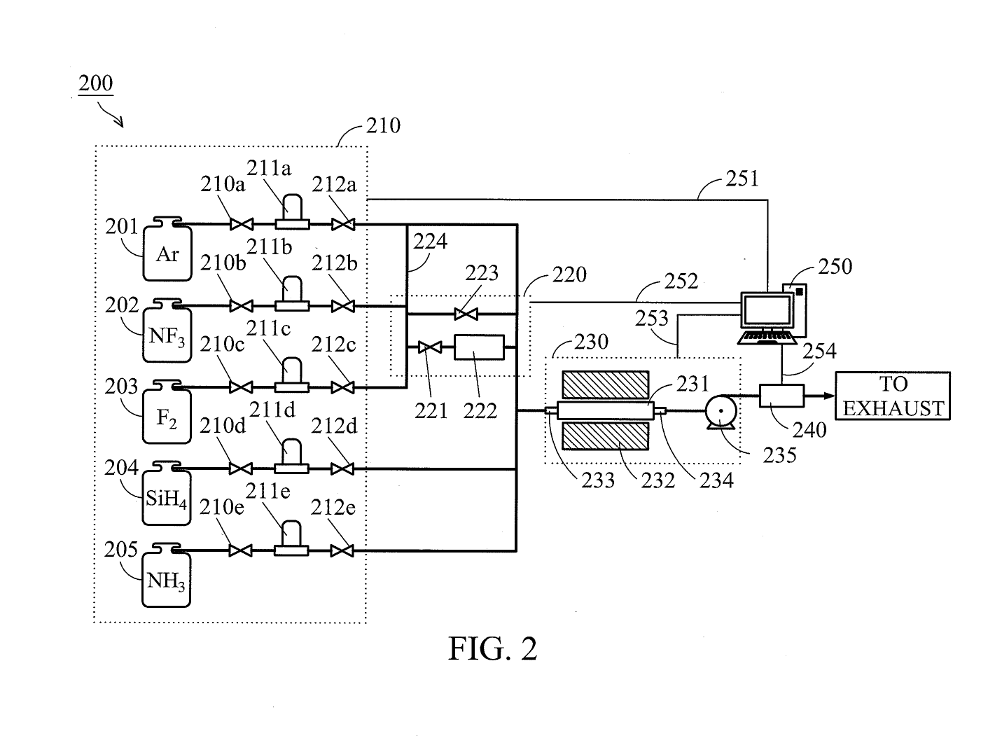

FIG. 2 illustrates a schematic diagram of a system 200 for a plasma-assisted cleaning process integrated with a reaction chamber, in accordance with some embodiments. In some embodiments, the system 200 for the plasma-assisted cleaning process includes a gas delivering system 210, a remote plasma system 220, a CVD reaction chamber furnace system 230, a gas analyzer 240 and a control computer 250. The gas delivering system 210 includes reactant gas tanks 204 and 205 containing SiH₄ and NH₃, for example, for use during deposition of Si and Si-containing compounds. In some embodiments, the reaction chamber is a tube furnace. A gas tank 201 with a carrier gas (e.g., Ar) can be directly connected to one end of the reaction chamber 231. In some embodiments, gas tanks 202 and 203 with reactant gasses for example NF₃ and F₂, respectively, can also be connected to the reaction chamber 231. On each gas supply line, a mass flow controller (MFC) 211a-211e (hereinafter “MFC 211”), an input valve 210a-210e, and an output valve 212a-212e are integrated and can be controlled separately by the control computer 250. The remote plasma system 220 includes a remote plasma source 222 with an input valve 221 and a bypass valve 223 connected to the gas lines of the reactant gases. In some embodiments, an Ar purge/carrier gas line 224 can also be connected to the remote plasma system 220.

The remote plasma system 220 is provided to periodically clean the reaction chamber 231. The remote plasma source 222 is connected to a plurality of reactant gas tanks, e.g., molecular fluorine, molecular hydrogen, or other fluorine-containing gases, such as hydrogen fluoride, nitrogen trifluoride and fluorocarbons, alone or in combination with another gas such as Ar. In some embodiments, molecular O₂ may be added to remove undesired fluorocarbon polymer residuals on the inner surface of the reaction chamber when the at least one reactant gas comprises fluorocarbon molecules (e.g., CF₄). In some embodiments, molecular N₂ may be added especially when etching silicon nitride, in accordance with some embodiments.

The active ionic species resulted from the remote plasma system 220 is transferred by a carrier gas to the reaction chamber 231 via the gas inlet 233. Materials between the remote plasma source 222 and the reaction chamber 231 may be resistant to attack by the plasma and distance between the plasma source 222 and the reaction chamber 231 should be kept as short as possible. Generating the cleaning plasma in the remote plasma source 222 allows the use of an efficient plasma generator and does not subject tubes to the temperature, radiation, or bombardment of the glow discharge that may be present in a plasma formed in-situ.

The CVD reaction chamber furnace system 230 may further include an insulated furnace housing (not shown), a thermal insulating material between the reaction chamber 231 and the furnace housing, e.g., Al₂O₃ fibrous, for energy efficiency. During the CVD process, reactant gases for deposition reactions, e.g., SiH₄ 204 and NH₃ 205, are introduced to reaction chamber 231 via the gas inlet connection 233, circulates through the reaction chamber 231 and stack of a plurality of wafers, and exits the reaction chamber 231 through an exhaust gas line 234 to a vacuum pump 235 as shown in FIG. 2. The reactant gas for a deposition reaction can be switched off and the reactant gas for cleaning processes can be switched on.

In some embodiments, the CVD reaction chamber furnace 230 may receive a wafer boat (not shown) that is configured and adapted for supporting and holding a plurality of vertically-stacked wafers. In one embodiment, reaction chamber 231 may be configured to allow the wafer boat to be inserted and removed from the reaction chamber for batch processing of wafers. In one embodiment, a wafer boat includes an open-frame structure such as a ladder-type design having multiple horizontal slots for supporting the wafers and allowing reactant gas to flow horizontally over the face of the wafers to build the desired material film thicknesses thereon. Wafer boat may be sized to hold 50-125 wafers or more in some embodiments; however, any suitable number of wafers may be held by the wafer boat depending on the height of the reaction chamber 231. Wafer boat may be made of quartz or any other suitable material. In some embodiments, wafer boat may be provided with a motor drive mechanism (not shown) to allow the stack of wafers to be rotated during the CVD process to promote uniform thickness of the layer of material deposited on the wafers.

Reaction chamber 231 may have a cylindrical shape in one embodiment and may be made of quartz, silicon carbide (SiC), or any other suitable materials. The reaction chamber 231 may include a tube deposit such as polysilicon or another Si-containing materials used depending on the type of processes conducted in the reaction chamber 231. The reaction chamber 231 may have any suitable height or length depending on the number and size of wafers to be processed in each batch. In some exemplary embodiments, the reaction chamber 231 may have a representative vertical height or length of 100-150 cm; however, any suitable height or length may be provided. The reaction chamber 231 for processing 450 mm wafers must be sized to more than about 450 mm diameter and chamber length of 50-200 cm, in accordance with some embodiments.

Other appurtenances used in conjunction with CVD reaction chamber 231 processing assemblies and semiconductor furnaces may be provided. For example, reaction gas supply inlet connections 233 and an exhaust gas line 234 may be furnished to allow one or more process gases to be introduced and removed from reaction chamber 231. Gas manifold and injectors, furnace cooling to allow precise control of a temperature profile and quick changing of wafer batches, an external insulated housing enclosing the reaction chamber 231, wafer boat elevator or lift and robotically-controlled arm for positioning, raising, and lowering the wafer boat into/from the reaction chamber 231, etc. (not shown) can be included in the CVD reaction chamber furnace system 230.

The operation of CVD reaction chamber furnace 230 and processing of wafers may be controlled by a suitable temperature PID (proportional-integral-derivative) controller to regulate the heat output from the furnace heating system including temperature ramp up and ramp down rates.

With continuing reference to FIG. 2, sidewall heaters 232 in one embodiment may be electric resistance type heaters having controllable heat output which may be regulated by adjusting the energy input to each heater via a variable resistance control such as a rheostat or other suitable similar electrical control device. The sidewall heaters 232 are disposed proximate to the external sidewall and are arranged in spaced vertical relationship to each other along the height of reaction chamber 231 with separate temperature controls. In some embodiments, the sidewall heaters 232 can define a plurality of vertical heater zones within reaction chamber 231 with the temperature in each zone being provided by a single heater 232. In some embodiments, the sidewall heaters 232 may include a metal alloy, for example Fe—Cr—Al alloy.

The heat output from the sidewall heaters 232 may be fine-tuned to adjust the temperature in each heater zone, in accordance with some embodiments. The heat output from each of the sidewall heaters 232 may be adjustable independent of the other sidewall heaters. The heat output setting of each sidewall heater may be adjusted automatically via a heater controller or computer 250 through connection 254 in conjunction with control signals generated by temperature sensors (e.g., thermocouples) disposed in the reaction chamber 231 and/or based on predetermined heater temperature output settings derived from experience and empirical data correlated with the size of wafer being processed and/or type of material film being deposited on the wafers.

The computer 250 provides control to the gas delivering system 210 including the MFCs 211, input/out valves 210 and 212 on each gas lines, and the remote plasma system 220 including the plasma source 222 and valves 221/223 through control connection 251 and 252. The computer can also receive input through connections 254 from an in-line gas analyzer 240 which is connected to the exhaust gas line 234 of the reaction chamber 231, by detecting the chemical composition of the exhaust gases. In some embodiments, the in-line gas analyzer 240 can be a Fourier Transform Infrared (FTIR) Spectrometer or a Gas chromatography-mass spectrometer (GCMS) or any other types of inline gas analyzers to provide an accurate and fast measurement of the volatile species composition, especially the Si concentration. In some embodiments, the measurement of gas exhaust composition using a FTIR spectrometer is based on the characteristic vibration and rotation features of molecules in gas phase at different frequencies, which are associated with energy states of a particular molecule. These modes are excited by the infrared radiation resulting in a unique IR absorption spectrum. This method provides capabilities to detect various gaseous chemicals, a fast detection, a wide detection range, and a low detection limit down to sub-parts per million (ppm) level.

In some embodiments, the Si concentration or the change of Si concentration can be used to determine a time to switch off the RF power on the remote plasma source 222, close the valve 221, and open the bypass valve 223 so as to directly supply the reaction gas for a chemical cleaning process to the reaction chamber 231 without going through the remote plasma source 222. In some embodiments, when the Si concentration or the change of the Si concentration reaches a predefined threshold value, the computer 250 can provide a control signal through the connection 253 to the reaction chamber heater 232 as well as the vacuum pump 235 to prepare a a temperature and pressure in the reaction chamber for the chemical cleaning process using molecular F₂. In some embodiments, the temperature and pressure are higher in the chemical cleaning process than that in the plasma-assisted cleaning process due to the higher activation energy of the reaction.

In one embodiment, a method for cleaning a deposition reaction chamber, the method comprising: performing a plasma-assisted cleaning process to clean tube deposits formed on an inner surface of the deposition reaction chamber, wherein the plasma-assisted cleaning process comprises: providing a first reactant gas to a remote plasma source chamber to generate a plasma, wherein the plasma comprising a fluorine-containing radical; and providing the plasma from the remote plasma source chamber to the deposition reaction chamber to clean the tube deposits, and performing a chemical cleaning process by providing a second reactant gas to the deposition reaction chamber after performing the plasma dry cleaning process.

In another embodiment, a dry cleaning system includes: a gas delivery system configured to provide at least one reactant gas; a semiconductor processing apparatus coupled to the gas delivery system; a remote plasma system connected to the gas delivery system and configured to receive the at least one reactant gas, convert the at least one reactant gas into a plasma and deliver the plasma to the semiconductor processing apparatus; a gas analyzer connected to the semiconductor processing apparatus and configured to perform an analysis on an exhaust gas from the semiconductor processing apparatus; and a control computer connected to and configured to control the gas delivery system, the semiconductor processing apparatus, the remote plasma system, and the gas analyzer, wherein the control computer controls the remote plasma system to provide the plasma to the semiconductor processing apparatus and thereafter, in response to an output from the gas analyzer, controls the gas delivery system to provide the at least one reactant gas to the reaction chamber.

Yet, in another embodiment, A non-transitory computer-readable medium storing computer-executable instructions thereon that when executed perform a method for dry cleaning a semiconductor processing reaction chamber, the method comprising: performing a plasma-assisted cleaning process to clean deposits formed on the semiconductor processing reaction chamber; and performing a chemical cleaning process to further clean the semiconductor processing reaction chamber, wherein the plasma-assisted cleaning process is a cleaning process using a plasma, wherein the plasma is formed by flowing at least one reactant gas into a remote plasma source chamber, and wherein the chemical cleaning process comprises flowing the reactant gas into the semiconductor processing reaction chamber.

While various embodiments of the disclosure have been described above, it should be understood that they have been presented by way of example only, and not by way of limitation. Likewise, the various diagrams may depict an example architectural or configuration, which are provided to enable persons of ordinary skill in the art to understand exemplary features and functions of the disclosure. Such persons would understand, however, that the disclosure is not restricted to the illustrated example architectures or configurations, but can be implemented using a variety of alternative architectures and configurations. Additionally, as would be understood by persons of ordinary skill in the art, one or more features of one embodiment can be combined with one or more features of another embodiment described herein. Thus, the breadth and scope of the present disclosure should not be limited by any of the above-described exemplary embodiments.

It is also understood that any reference to an element herein using a designation such as “first,” “second,” and so forth does not generally limit the quantity or order of those elements. Rather, these designations can be used herein as a convenient means of distinguishing between two or more elements or instances of an element. Thus, a reference to first and second elements does not mean that only two elements can be employed, or that the first element must precede the second element in some manner.

Additionally, a person having ordinary skill in the art would understand that information and signals can be represented using any of a variety of different technologies and techniques. For example, data, instructions, commands, information, signals, bits and symbols, for example, which may be referenced in the above description can be represented by voltages, currents, electromagnetic waves, magnetic fields or particles, optical fields or particles, or any combination thereof.

A person of ordinary skill in the art would further appreciate that any of the various illustrative logical blocks, modules, processors, means, circuits, methods and functions described in connection with the aspects disclosed herein can be implemented by electronic hardware (e.g., a digital implementation, an analog implementation, or a combination of the two), firmware, various forms of program or design code incorporating instructions (which can be referred to herein, for convenience, as “software” or a “software module), or any combination of these techniques.

To clearly illustrate this interchangeability of hardware, firmware and software, various illustrative components, blocks, modules, circuits, and steps have been described above generally in terms of their functionality. Whether such functionality is implemented as hardware, firmware or software, or a combination of these techniques, depends upon the particular application and design constraints imposed on the overall system. Skilled artisans can implement the described functionality in various ways for each particular application, but such implementation decisions do not cause a departure from the scope of the present disclosure. In accordance with various embodiments, a processor, device, component, circuit, structure, machine, module, etc. can be configured to perform one or more of the functions described herein. The term “configured to” or “configured for” as used herein with respect to a specified operation or function refers to a processor, device, component, circuit, structure, machine, module, etc. that is physically constructed, programmed and/or arranged to perform the specified operation or function.

Furthermore, a person of ordinary skill in the art would understand that various illustrative logical blocks, modules, devices, components and circuits described herein can be implemented within or performed by an integrated circuit (IC) that can include a general purpose processor, a digital signal processor (DSP), an application specific integrated circuit (ASIC), a field programmable gate array (FPGA) or other programmable logic device, or any combination thereof. The logical blocks, modules, and circuits can further include antennas and/or transceivers to communicate with various components within the network or within the device. A general purpose processor can be a microprocessor, but in the alternative, the processor can be any conventional processor, controller, or state machine. A processor can also be implemented as a combination of computing devices, e.g., a combination of a DSP and a microprocessor, a plurality of microprocessors, one or more microprocessors in conjunction with a DSP core, or any other suitable configuration to perform the functions described herein.

If implemented in software, the functions can be stored as one or more instructions or code on a computer-readable medium. Thus, the steps of a method or algorithm disclosed herein can be implemented as software stored on a computer-readable medium. Computer-readable media includes both computer storage media and communication media including any medium that can be enabled to transfer a computer program or code from one place to another. A storage media can be any available media that can be accessed by a computer. By way of example, and not limitation, such computer-readable media can include RAM, ROM, EEPROM, CD-ROM or other optical disk storage, magnetic disk storage or other magnetic storage devices, or any other medium that can be used to store desired program code in the form of instructions or data structures and that can be accessed by a computer.

In this document, the term “module” as used herein, refers to software, firmware, hardware, and any combination of these elements for performing the associated functions described herein. Additionally, for purpose of discussion, the various modules are described as discrete modules; however, as would be apparent to one of ordinary skill in the art, two or more modules may be combined to form a single module that performs the associated functions according embodiments of the disclosure.

Additionally, memory or other storage, as well as communication components, may be employed in embodiments of the disclosure. It will be appreciated that, for clarity purposes, the above description has described embodiments of the disclosure with reference to different functional units and processors. However, it will be apparent that any suitable distribution of functionality between different functional units, processing logic elements or domains may be used without detracting from the disclosure. For example, functionality illustrated to be performed by separate processing logic elements, or controllers, may be performed by the same processing logic element, or controller. Hence, references to specific functional units are only references to a suitable means for providing the described functionality, rather than indicative of a strict logical or physical structure or organization.

Various modifications to the implementations described in this disclosure will be readily apparent to those skilled in the art, and the general principles defined herein can be applied to other implementations without departing from the scope of this disclosure. Thus, the disclosure is not intended to be limited to the implementations shown herein, but is to be accorded the widest scope consistent with the novel features and principles disclosed herein, as recited in the claims below.

What is claimed is:

1. A method for cleaning a deposition reaction chamber, the method comprising:
performing a plasma-assisted cleaning process to clean tube deposits formed on an inner surface of the deposition reaction chamber, wherein the plasma-assisted cleaning process comprises:
providing a first reactant gas to a remote plasma source chamber to generate a plasma, wherein the plasma comprising a fluorine-containing radical; and
providing the plasma from the remote plasma source chamber to the deposition reaction chamber to clean the tube deposits, and
performing a chemical cleaning process by providing a second reactant gas to the deposition reaction chamber after performing the plasma dry cleaning process.

2. The method of claim 1, wherein the deposition reaction chamber comprises quartz or silicon carbide.

3. The method of claim 1, wherein the tube deposits comprise silicon (Si) or Si-containing compounds.

4. The method of claim 1, wherein the first reactant gas comprises one of the following: molecular fluorine and nitrogen trifluoride.

5. The method of claim 4, wherein the first reactant gas further comprises argon.

6. The method of claim 1, further comprising,
determining a time to switch from the plasma-assisted cleaning process to the chemical cleaning process, wherein the determining comprises:
obtaining a gas exhaust from the deposition reaction chamber;
analyzing the gas exhaust;
calculating a semiconductor material concentration in the gas exhaust; and
determining whether the semiconductor material concentration is equal to
or smaller than a predetermined threshold value.

7. The method of claim 6, wherein the analyzing is performed by an in-line gas analyzer coupled to an exhaust of the deposition reaction chamber.

8. The method of claim 1, wherein the plasma-assisted cleaning process is performed at a first pressure and the chemical cleaning process is performed at a second pressure, wherein the second pressure is different from the first pressure.

9. The method of claim 1, wherein the plasma-assisted cleaning process is performed at a first temperature and the chemical cleaning process is performed at a second temperature, wherein the second temperature is different from the first temperature.

10. A dry cleaning system comprising:
a gas delivery system configured to provide at least one reactant gas;
a semiconductor processing apparatus coupled to the gas delivery system;
a remote plasma system connected to the gas delivery system and configured to receive the at least one reactant gas, convert the at least one reactant gas into a plasma and deliver the plasma to the semiconductor processing apparatus;
a gas analyzer connected to the semiconductor processing apparatus and configured to perform an analysis on an exhaust gas from the semiconductor processing apparatus; and
a control computer connected to and configured to control the gas delivery system, the semiconductor processing apparatus, the remote plasma system, and the gas analyzer, wherein the control computer controls the remote plasma system to provide the plasma to the semiconductor processing apparatus and thereafter, in response to an output from the gas analyzer, controls the gas delivery system to provide the at least one reactant gas to the reaction chamber.

11. The system of claim 10, wherein the gas delivery system is further configured to provide at least one reactant gas comprising a silicon (Si)-containing gas to the semiconductor processing apparatus.

12. The system of claim 10, wherein the gas analyzer is a Fourier Transform Infrared spectrometer.

13. The system of claim 10, wherein the semiconductor processing apparatus comprises a deposition reaction chamber, at least one heater, and a pump connected to the deposition reaction chamber.

14. The system of claim 13, wherein the deposition reaction chamber comprises quartz or silicon carbide.

15. The system of claim 10, wherein the gas analyzer is configured to:
receive the exhaust gas from the semiconductor processing apparatus; and
measure a chemical composition of the exhaust gas.

16. The system of claim 10, wherein the control computer is further configured to:
configure the gas delivery system and the semiconductor processing apparatus to establish a first temperature and pressure for performing a semiconductor manufacturing processing step;
configure the gas delivery system and the semiconductor processing apparatus to establish a second temperature and pressure for performing a plasma-assisted cleaning process; and
configure the gas delivery system and the semiconductor processing apparatus to establish a third temperature and pressure for performing a chemical cleaning process.

17. The system of claim 16, wherein the third pressure and temperature each are greater than the second pressure and temperature, respectively.

18. The system of claim 10, wherein the gas analyzer is coupled to an exhaust gas line of the semiconductor processing apparatus.

19. A non-transitory computer-readable medium storing computer-executable instructions thereon that when executed perform a method for dry cleaning a semiconductor processing reaction chamber, the method comprising:
performing a plasma-assisted cleaning process to clean deposits formed on the semiconductor processing reaction chamber; and
performing a chemical cleaning process to further clean the semiconductor processing reaction chamber,
wherein the plasma-assisted cleaning process is a cleaning process using a plasma, wherein the plasma is formed by flowing at least one reactant gas into a remote plasma source chamber, and wherein the chemical cleaning process comprises flowing the reactant gas into the semiconductor processing reaction chamber.

20. The non-transitory computer-readable medium of claim 19, wherein the method further comprises determining a time to switch from the plasma dry cleaning process to the chemical cleaning process, wherein the determining comprises:
obtaining an exhaust gas sample from the semiconductor processing reaction chamber;
analyzing the exhaust gas sample;
calculating a silicon (Si) concentration in the exhaust gas sample; and
determining whether the Si concentration is equal to or smaller than a predetermined threshold value.
